(19) United States
(12) Patent Application Publication
(10) Pub. No.: US 2026/0247528 A1
(43) Pub. Date: Aug. 20, 2026

(54) PRINTED CIRCUIT BOARD AND MANUFACTURING METHOD OF PRINTED CIRCUIT BOARD

(71) Applicant: SAMSUNG ELECTRO-MECHANICS CO., LTD., Suwon-si (KR)

(72) Inventors: Yong Suk KIM, Suwon-si (KR); Kwang Su KIM, Suwon-si (KR); Joung Hun KIM, Suwon-si (KR); Tae Kyung LEE, Suwon-si (KR); Jin Uk LEE, Suwon-si (KR)

(73) Assignee: SAMSUNG ELECTRO-MECHANICS CO., LTD., Suwon-si (KR)

(21) Appl. No.: 19/419,301

(22) Filed: Dec. 15, 2025

(30) Foreign Application Priority Data
Feb. 20, 2025 (KR) 10-2025-0022320
May 12, 2025 (KR) 10-2025-0061287

(51) Int. Cl. H05K 1/02; H05K 1/11; H05K 3/46

(52) U.S. Cl. CPC H05K 1/0298; H05K 1/115; H05K 3/4644

(57) ABSTRACT

A printed circuit board includes a main portion including a plurality of insulating layers and a plurality of conductor layers laminated in a first direction, a margin portion disposed on an outside of the main portion in a second direction, and including an insulator connected to the insulating layers of the main portion, and at least one pad disposed on the main portion, wherein, when a portion of an upper surface of the main portion, covered by the pad is referred to as a cover surface, and a portion of the upper surface, not covered by the pad is referred to as an open surface, at least a portion of the upper surface of the margin portion is located above the cover surface based on the first direction.

### CROSS-REFERENCE TO RELATED APPLICATIONS

This application claims benefit of priority to Korean Patent Application Nos. 10-2025-0022320 filed on Feb. 20, 2025 and 10-2025-0061287 filed on May 12, 2025 in the Korean Intellectual Property Office, the disclosures of which are incorporated herein by reference in its entirety.

### BACKGROUND

### Filled

The present disclosure relates to a printed circuit board and a manufacturing method of the printed circuit board.

### Description of Related Art

Recently, due to the development of artificial intelligence (AI) technology and other technologies, packages including memory chips such as High Bandwidth Memory (HBM) for exponentially increasing data processing, and processor chips such as a Central Processing Unit (CPU), a Graphics Processing Unit (GPU), an Application Specific Integrated Circuit (ASIC), and a Field Programmable Gate Array (FPGA) are being used. In this regard, as the development of semiconductor microprocessing technology is delayed and the issue of rapid cost increases due to miniaturization occurs, the importance of packaging technology is rising, and major companies are focusing on securing competitiveness in advanced semiconductor packaging technology. To meet these technological requirements, technologies utilizing silicon interposers have been developed, but commercialization thereof may be limited due to price issues and complex assembly processes.

### SUMMARY

An aspect of the present disclosure is to provide a printed circuit board having improved structural stability, and such a printed circuit board may be suitable for use as a bridge substrate. In addition, the present disclosure may provide a manufacturing method for efficiently manufacturing a printed circuit board.

According to an embodiment, provided is a printed circuit board,

the printed circuit board including: a main portion including a plurality of insulating layers and a plurality of conductor layers laminated in a first direction, a margin portion disposed on an outside of the main portion in a second direction, and including an insulator connected to the insulating layers of the main portion, and at least one pad disposed on the main portion, wherein when a portion of an upper surface of the main portion, covered by the at least one pad is referred to as a cover surface, and a portion of the upper surface, not covered by the at least one pad is referred to as an open surface, at least a portion of an upper surface of the margin portion is located above the cover surface based on the first direction.

In an embodiment, the insulating layers of the main portion and the insulator of the margin portion may form an integral structure.

In an embodiment, in the margin portion, a region located above the cover surface and a region located below the cover surface may form an integral structure.

In an embodiment, the insulating layers of the main portion and the insulator of the margin portion may be formed of the same material.

In an embodiment, the margin portion may not include a conductor layer connected to the conductor layers of the main portion.

In an embodiment, the margin portion may not include a conductor layer.

In an embodiment, a portion of the margin portion may contact a side surface of the at least one pad.

In an embodiment, an outer surface of the margin portion may be a cut surface.

In an embodiment, when a direction, perpendicular to the first direction and perpendicular to each other is referred to as a second direction and as a third direction, the margin portion may be disposed on the outside of the main portion in the second direction and the third direction.

In an embodiment, the upper surface of the margin portion may have a height decreasing toward an outer edge in the second direction.

In an embodiment, the upper surface of the margin portion may include a curved surface having a recessed form.

In an embodiment, all regions of the upper surface of the margin portion may be located above the cover surface of the margin portion.

In an embodiment, at least a portion of the upper surface of the margin portion may be located below an upper surface of the at least one pad.

In an embodiment, all regions of the upper surface of the margin portion may be located below the upper surface of the at least one pad.

In an embodiment, the cover surface and the open surface may be located on substantially the same level based on the first direction.

In an embodiment, the open surface may be a substantially flat surface.

In an embodiment, the open surface may be located above the cover surface based on the first direction.

In an embodiment, the open surface may include a curved surface.

In an embodiment, at least a portion of the upper surface of the margin portion may be located below the open surface based on the first direction.

In an embodiment, the open surface may be a substantially flat surface.

In an embodiment, an uppermost portion of the upper surface of the margin portion may be located on substantially the same level as the open surface.

In an embodiment, at least a portion of the upper surface of the margin portion may be located above the open surface based on the first direction.

In an embodiment, the at least one pad are provided in plural, and a distance between adjacent pads among a plurality of pads may be less than a width of the margin portion.

In an embodiment, the open surface is a substantially flat surface, and the upper surface of the margin portion may include a curved surface.

In an embodiment, the upper surface of the margin portion may be a substantially flat surface.

In an embodiment, the conductor layers may be disposed further inwardly in the second direction than one of the at least one pad, disposed on an outermost side in the second direction.

In an embodiment, the margin portion may include a separate conductor layer, separated from the conductor layers of the main portion.

In an embodiment, a portion of the conductor layers may be disposed further outwardly in the second direction than one of the at least one pad, disposed on an outermost side in the second direction.

In an embodiment, the margin portion may include a portion of the conductor layers of the main portion.

According to another aspect of the present disclosure, provided is a printed circuit board including a substrate portion and a bridge substrate embedded in the substrate portion, wherein the bridge substrate includes a main portion including a plurality of insulating layers and a plurality of conductor layers laminated in a first direction, a margin portion disposed on an outside of the main portion in a second direction, and including an insulator connected to the insulating layers of the main portion, and at least one pad disposed on the main portion, wherein at least a portion of an upper surface of the margin portion is located above a lower surface of the at least one pad based on the first direction.

In an embodiment, the bridge substrate is disposed in a recess of the substrate portion.

In an embodiment, the recess may further include an insulating material covering the bridge substrate.

In an embodiment, the insulating material may form an interface with the insulator of the margin portion.

In an embodiment, the insulating material and the insulator of the margin portion may include different materials.

In an embodiment, the substrate may further include a plurality of via layers penetrating through the insulating material and connected to the at least one pad of the bridge substrate.

In an embodiment, the conductor layer of the bridge substrate and the substrate portion may include a plurality of conductor patterns, and an average distance between the plurality of conductor patterns of the bridge substrate may be less than an average distance between the plurality of conductor patterns of the substrate portion.

According to another aspect of the present disclosure, provided is a method of manufacturing a printed circuit board,

the method including: forming a substrate laminate by laminating a plurality of insulating layers and a plurality of conductor layers, forming a plurality of pads on a plurality of printed circuit board regions among the substrate laminates, filling an insulator into a margin region between adjacent regions of the plurality of printed circuit board regions, and separating the substrate laminate into unit substrates by dicing the margin region filled with the insulator.

In an embodiment, the forming the substrate laminate may include preparing a carrier, and repeatedly forming the plurality of insulating layers and the plurality of conductor layers on the carrier.

In an embodiment, the method may further include attaching a transfer substrate to the substrate laminate, and separating the carrier from the substrate laminate.

In an embodiment, prior to the filling the insulator, an upper surface height of the margin region may be lower than an upper surface height of the printed circuit board region.

In an embodiment, in the filling the insulator, the insulator may be filled higher than a region thereof, covered by the plurality of pads on an upper surface of the substrate laminate.

In an embodiment, in the filling the insulator, a portion of the insulator may also be filled into the printed circuit board region.

In an embodiment, in the filling the insulator, a portion of the insulator may cover the plurality of pads.

In an embodiment, the method may further include removing at least a portion of the insulator filled into the printed circuit board region.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board;

FIG. 3 is a plan view of the printed circuit board of FIG. 2 viewed from one direction;

FIG. 4 is a cross-sectional view schematically illustrating a modified example of a printed circuit board;

FIG. 5 is a cross-sectional view schematically illustrating a modified example of a printed circuit board;

FIG. 6 is a cross-sectional view schematically illustrating a modified example of a printed circuit board;

FIG. 7 is a cross-sectional view schematically illustrating a modified example of a printed circuit board;

FIG. 8 is a cross-sectional view schematically illustrating a modified example of a printed circuit board;

FIG. 9 is a cross-sectional view schematically illustrating a modified example of a printed circuit board;

FIGS. 10, 11, 12, 13, 14 and 15 illustrate an example of a manufacturing process of a printed circuit board;

FIG. 16 is a cross-sectional view schematically illustrating a modified example of a printed circuit board; and

FIG. 17 is a cross-sectional view schematically illustrating an example of a printed circuit board including a bridge substrate.

### DETAILED DESCRIPTION

Hereinafter, embodiments of the present disclosure will be described as follows with reference to the attached drawings. The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. Accordingly, shapes and sizes of elements in the drawings may be exaggerated for clear description, and elements indicated by the same reference numerals are the same elements in the drawings.

### Electronic device

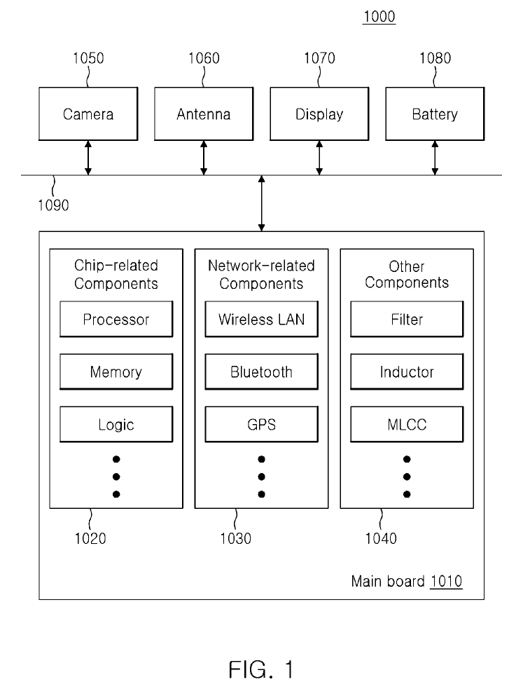

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access + (HSPA+), high speed downlink packet access + (HSDPA+), high speed uplink packet access + (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

The aforementioned other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

### Printed circuit board

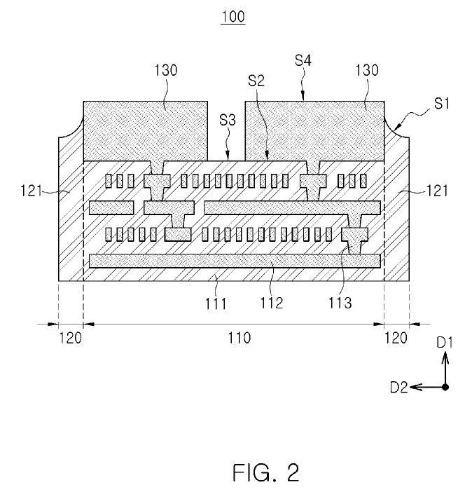

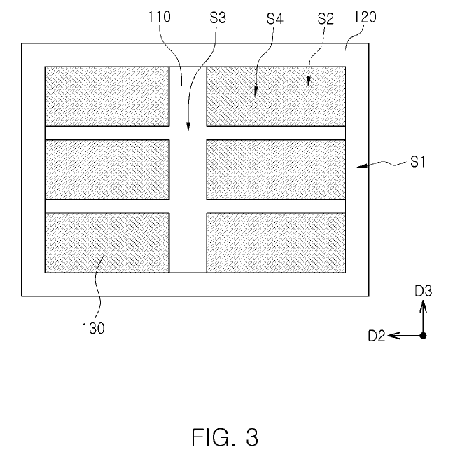

FIG. 2 is a cross-sectional view schematically illustrating an example of a printed circuit board. FIG. 3 is a plan view of the printed circuit board of FIG. 2 viewed from one direction. Referring to FIGS. 2 and 3, a printed circuit board 100 according to the present embodiment includes a main portion 110 including a plurality of insulating layers 111 and a plurality of conductor layers 112 laminated in a first direction D1, a margin portion 120, and at least one pad 130. An upper surface of the margin portion 120 is formed relatively high. Specifically, when a surface of the upper surface of the main portion 110, covered by the pad 130, is referred to as a cover surface S2, and a surface thereof, not covered by the pad 130 is referred to as an open surface S3, at least a portion of the upper surface S1 of the margin portion 120 is located above the cover surface S2 of the main portion 110 based on a first direction D1. Even if there is no specific explanation below, when comparing levels of surfaces, the first direction D1 is used as a reference, and the higher the position in the drawing, the higher the level. In general, in the printed circuit board 100, the margin portion 120 has a smaller conductor layer than the main portion 110 and is formed thinner than the margin portion 120. In this case, there is a high possibility of defects occurring during the manufacturing process of the printed circuit board 100, and the structural stability may also be reduced when used as a bridge substrate, or the like. In this embodiment, a height of the upper surface S1 of the margin portion 120 may be implemented to be higher than at least a portion of the main portion 110, for example, the cover surface S2 covered by the pad 130, thereby reducing a defect rate during the manufacturing process and improving structural stability. The printed circuit board 100 is suitable for use as a bridge substrate, but may also be used as a general-purpose board other than a bridge substrate. Hereinafter, the main components of the printed circuit board 100 are described in detail.

The main portion 110 is a region performing the main function of the substrate in the printed circuit board 100, and includes a plurality of insulating layers 111 and a plurality of conductor layers 112 laminated in a first direction D1. The insulating layer 111 includes an insulating material, wherein the insulating material may be an organic insulating material such as a photosensitive insulating material (PID). When a photosensitive insulating material (PID) is used as a material of the insulating layer 111, a thickness of the insulating layer 111 may be minimized, and a photo via hole may be formed, so that a plurality of conductor layers 112 may be designed at a high density. However, the material of the insulating layer 111 is not limited thereto, and other organic insulating materials such as ABF may also be used. If necessary, an inorganic insulating material such as silicon may be included. A plurality of insulating layers 111 may be provided and laminated, and the number of layers laminated here is not particularly limited. In this case, boundaries of the plurality of insulating layers 111 may be distinct from each other or may be unclear.

When the plurality of conductor layers 112 is used as a bridge substrate, the plurality of conductor layers 112 may provide a die-to-die interconnection path, and the number of layers is particularly limited. The plurality of conductor layers 112 may perform various functions depending on the design of a corresponding layer, and may include at least a signal pattern. Each of the plurality of conductor layers 112 may include a line pattern, a plane pattern, and/or a pad pattern. Each of the plurality of conductor layers 112 may include a metal material such as copper (Cu), aluminum (Al), silver (Ag), tin (Sn), gold (Au), nickel (Ni), lead (Pb), titanium (Ti), or alloys thereof. Each of the plurality of conductor layers 112 may include an electroless plating layer (or chemical copper) and/or an electrolytic plating layer (or electrolytic copper), and may include a sputtering layer, if necessary.

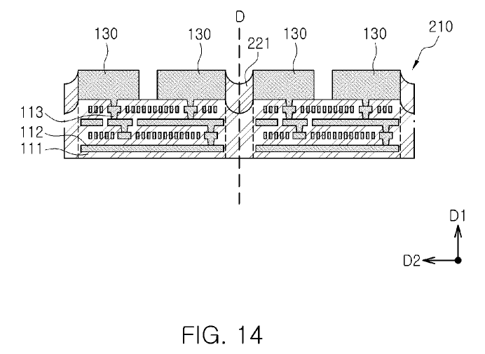

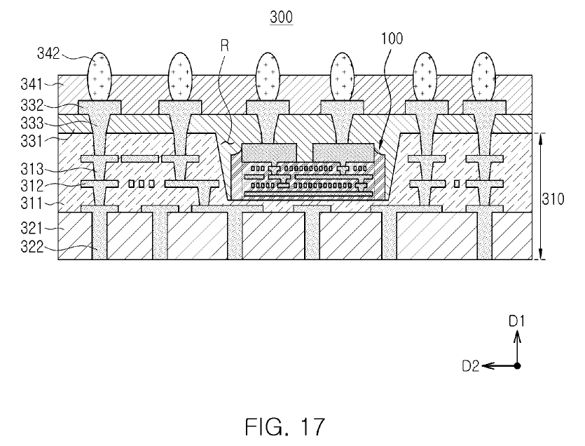

When the printed circuit board 100 is used as a bridge substrate, the plurality of conductor layers 112 may have a higher circuit density than the conductor pattern (312 in FIG. 14) included in a mother board, which will be described later with respect to the embodiment of FIG. 17. The plurality of conductor layers 112 may have two layers of high-density wiring layers and one layer of ground layer, and a line pattern for signal transmission may be omitted in the ground layer, but an embodiment thereof is not limited thereto. The high-density wiring layer may have only one design rule, such as line/space, for example, L/S of 2µm/2µm or 1µm/1µm, but an embodiment thereof is not limited thereto. A plurality of conductor layers 112 may be electrically connected to each other through conductive vias 113. The conductive vias 113 may include a metal material such as copper (Cu), aluminum (Al), silver (Ag), tin (Sn), gold (Au), nickel (Ni), lead (Pb), titanium (Ti), or alloys thereof, respectively. Each of the conductive vias 113 may include an electroless plating layer (or chemical copper) and/or an electrolytic plating layer (or electrolytic copper), and may include a sputtering layer, if necessary. Each of the conductive vias 113 may be a filled-type via filling a via hole with a metal material, but an embodiment thereof is not limited thereto, and may be a conformal-type via in which a metal material is disposed along a wall surface of the via hole. Each of the conductive vias 113 may have a tapered shape in which a width of an upper end portion thereof is wider than a width of a lower end portion thereof in cross-section. Each of the conductive vias 113 may perform various functions depending on the design of a corresponding layer, and may include, for example, a ground via, a power via, a signal via, or the like. Here, the signal via may include a via for transmitting various signals, such as a data signal, other than a ground via, a power via, or the like. The conductive via 113 may include a laminated via and/or a staggered via, depending on a vertical connection form.

The margin portion 120 is disposed on the outside of the main portion 110 in a lateral direction, and includes an insulator 121 connected to the insulating layer 111 of the main portion 110. Here, the lateral direction of the main portion 110 may include a second direction D2, perpendicular to the first direction D1. In addition, a direction, perpendicular to the first direction D1 and the second direction D2 may be defined as a third direction D3. The insulator 121 of the margin portion 120 may include an organic insulating material, such as a photosensitive insulating material (PID), and may include the same material as the insulating layer 111 of the main portion 110. However, the insulator 121 of the margin portion 120 may also include an inorganic insulating material, such as silicon. In relation to the manufacturing process, the insulating layer 111 of the main portion 110 and the insulator 121 of the margin portion 120 may be obtained by laminating the same insulating layers. Accordingly, the insulating layer 111 of the main portion 110 and the insulator 121 of the margin portion 120 may form an integral structure. In addition, the insulating layer 111 of the main portion 110 and the insulator 121 of the margin portion 120 may be formed of the same material.

As described later, the margin portion 120 may be provided as a dicing region for separating unit substrates during the manufacturing process of the printed circuit board 100, and in this case, when the margin portion 120 is thin, there may be a high possibility that a defect (e.g., a defect in which the printed circuit board 100 is not separated from a carrier) may occur. In the present embodiment, the margin portion 120 is formed relatively thick to secure structural stability, and specifically, at least a portion of the upper surface S1 of the margin portion 120 is located above the cover surface S2 of the upper surface of the main portion 110. As will be described later, the margin portion 120 may be thickened by adding an insulator to the dicing region. When a subsequent hardening process is performed, a region located above and a region disposed below the cover surface S2 in the margin portion 120 can form an integral structure without a distinct boundary. As described above, when the margin portion 120 is formed thickly so that the upper surface S1 is located above the cover surface S2 of the main portion 110, the pad 130, or the like may be effectively protected, and when the margin portion 120 is used as a bridge substrate or the like, a contact area with a mother substrate may be increased, thereby improving structural stability. In addition, when the margin portion 120 is thin, a de-bonding defect in which the printed circuit board 100 is not properly separated from the carrier, when the printed circuit board 100 is separated from the carrier, may occur. However, by forming the margin portion 120 thick as in the present embodiment, such a defect may be reduced.

In the present embodiment, the margin portion 120 may not include a conductor layer connected to a conductor layer 112 of the main portion 110. In other words, the conductor layer 112 of the main portion 110 may have a limited range of extension in a lateral direction, for example, the second direction D2, and may not extend to the margin portion 120. Accordingly, a dicing process may be effectively performed through the margin portion 120. Furthermore, the margin portion 120 may not include any conductor layers, as the margin portion 120 does not include a conductor layer connected to the conductor layer 112 of the main portion 110 or a conductor layer not connected thereto.

At least one pad 130 may be disposed on the main portion 110, and may have a plurality of pads 130 as in the present embodiment. In this case, a surface, covered by the pad 130 on the main portion 110 may be defined as a cover surface S2, and a surface, not covered by the pad 130 may be defined as an open surface S3. The pad 130 may perform various functions, including a signal pad, a ground pad, a power pad, or the like, and may include at least a signal pad 130. The pad 130 may include a metal material such as copper (Cu), aluminum (Al), silver (Ag), tin (Sn), gold (Au), nickel (Ni), lead (Pb), titanium (Ti), or alloys thereof. The pad 130 may be formed through a plating process, and may include, but an embodiment thereof is not limited thereto, an electroless plating layer (or chemical copper) and an electrolytic plating layer (or electrolytic copper). The pad 130 may include a sputtering layer, if necessary. The pad 130 may be connected to the conductor layer 112 disposed on the uppermost side among the conductor layers 112 through the conductive via 113 disposed on the uppermost side among the conductive vias 113.

Looking specifically at the form of the margin portion 120, particularly the shape of the upper surface S1 of the margin portion 120, first, a portion of the margin portion 120 may contact a side surface of the pad 130. An outer surface of the margin portion 120 may be a cut surface, which corresponds to a case in which the margin portion 120 is provided as a dicing region for separating the margin portion 120 into unit substrates as described above. Referring to FIG. 3, the margin portion 120 may be disposed on the outside of the main portion 110 in the second direction D2 and the third direction D3. In this case, the margin portion 120 may have a form surrounding the entire side surface of the main portion 110.

As illustrated in the form in FIG. 2, an upper surface S1 of the margin portion 120 may have a height decreasing toward the outer edge in the lateral direction, for example, the second direction D2. In addition, the upper surface S1 of the margin portion 120 may include a curved surface having a recessed form. As described above, when a height of the upper surface S1 of the margin portion 120 is changed or is implemented as a curved surface, a surface area of the margin portion may increase, thereby improving structural stability when the printed circuit board 100 is used as a bridge substrate. In the case of a structure in which the height of the upper surface S1 of the margin portion 120 decreases toward the outer edge in the lateral direction, for example, the second direction D2, or in the case of a structure in which the upper surface S1 of the margin portion 120 includes a curved surface of a recessed form, as described later, it may be formed in the process of filling the margin portion 120 with a liquid insulator including a photosensitive resin, or the like.

As illustrated in the form in FIG. 2, all regions of the upper surface S1 of the margin portion 120 may be located above the cover surface S2 of the main portion 110, and as the thickness of the main portion 110 is sufficiently secured, structural stability may be secured during the debonding process of separating the printed circuit board 100 from the carrier. However, the thickness of the margin portion 120 may be limited to a range that does not excessively increase the volume of the printed circuit board 100 and does not interfere with the electrical connectivity of the pad 130. In this case, at least a portion of the upper surface S1 of the margin portion 120 may be located below an upper surface S4 of the pad 130, and more specifically, all regions of the upper surface S1 of the margin portion 120 may be located below the upper surface S4 of the pad 130.

Meanwhile, regarding the shape of the upper surface of the main portion 110, the cover surface S2 and the open surface S3 may be located on substantially the same level based on the first direction D1. In this case, as illustrated in FIG. 2, the open surface S3 of the main portion 110 may be a substantially flat surface. As will be described later, an insulator supplemented to the margin portion 120 may also be applied to the open surface S3 of the main portion 110, and a portion of the main portion 110 may be raised in a region thereof, not covered by the pad 130, and accordingly, the cover surface S2 and the open surface S3 may be located on substantially the same level.

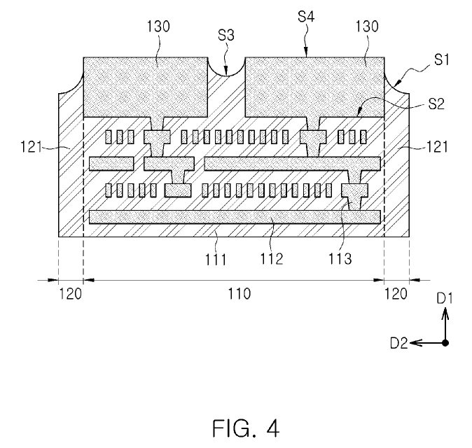

Hereinafter, modified embodiments will be described with reference to FIGS. 4 to 9. First, in the modified example of FIG. 4, there is a difference in the form of an open surface S3 of a main portion 110. Specifically, the open surface S3 of the main portion 110 may be located above a cover surface S2 based on the first direction D1. In this case, the open surface S3 of the main portion 110 may include a curved surface as illustrated in the diagram. As described above, in the process of supplementing and filling the margin portion 120 with a liquid insulator including a photosensitive resin, or the like, the liquid insulator may also be applied to the upper surface of the main portion 110, and accordingly, a form in which the open surface S3 of the main portion 110 located above the cover surface S2 may be obtained. In addition, when a gap between adjacent pads among the plurality of pads 130 is relatively wide, the open surface S3 of the main portion 110 may be formed to have a curved surface. When the height of the open surface S3 of the main portion 110 increases, the bonding force between the plurality of pads 130 may increase, thereby ensuring structural stability and further reducing the occurrence of defects during a subsequent de-bonding process of the printed circuit board 100.

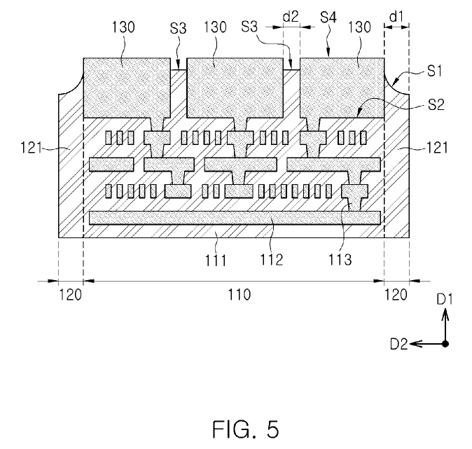

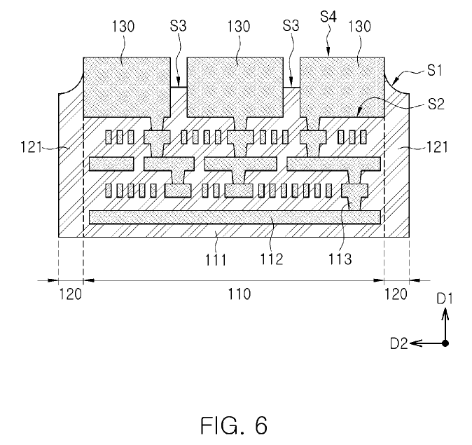

Next, in the modified example of FIG. 5, the open surface S3 of the main portion 110 is provided as a flat surface while being located on a relatively high level, which may be a form obtained as the width of the open surface S3 is reduced. Specifically, based on the first direction D1, the open surface S3 of the main portion 110 may be located above the cover surface S2, and at least a portion of the upper surface S1 of the margin portion 120 may be located below the open surface S3. In this case, the open surface of the main portion 110 may be substantially flat, as illustrated in the diagram. In addition, the uppermost portion of the upper surface S1 of the margin portion 120 may be located on substantially the same level as the open surface S3 of the main portion 110. A distance (d2) between adjacent pads among the plurality of pads 130 may be less than the width (d1) of the margin portion 120. Accordingly, the insulator filled between the pads 130 may have a flat upper surface, unlike the main portion 110. That is, the open surface S3 of the main portion 110 may be substantially flat, while the upper surface S1 of the margin portion 120 may include a curved surface. Meanwhile, in the modified example of FIG. 6, the level of the open surface S3 is slightly lowered, and at least a portion of the upper surface S1 of the margin portion 120 is located above the open surface S3. This form may be obtained by removing a portion of the insulation filled between the plurality of pads 130 in a range in which the open surface S3 of the main portion 110 remains on a higher level than the cover surface S2.

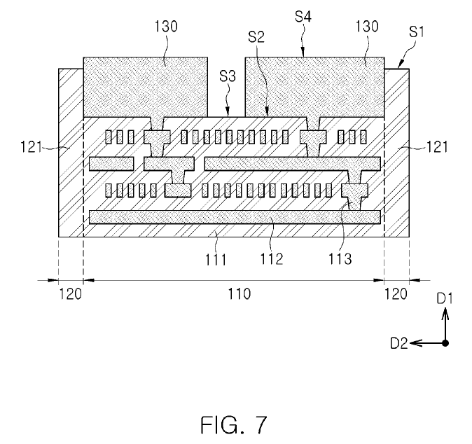

In the above-described embodiment, when the upper surface S1 of the margin portion 120 has a curved surface, in particular, a recessed form, but as in the modified example of FIG. 7, the upper surface S1 of the margin portion 120 may also be implemented as a substantially flat surface.

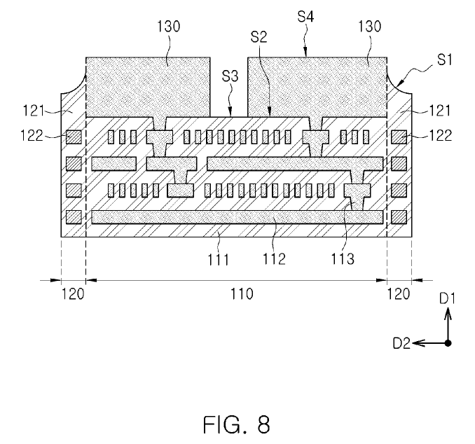

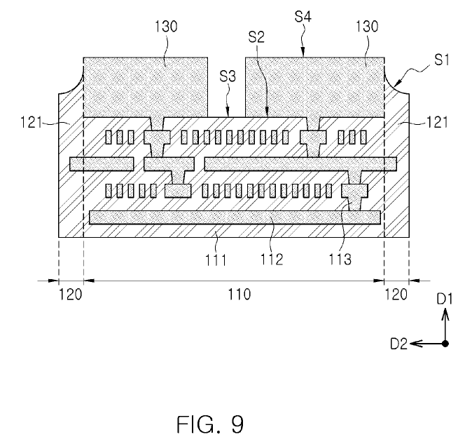

Meanwhile, in the case of a modified example of FIG. 8, the margin portion 120 includes a conductor layer 122, and in the case of a modified example of FIG. 9, there is a difference from the previous embodiment in a region in which the conductor layer 112 of the main portion 110 is disposed. That is, in the previous embodiment, the conductor layer 112 is disposed further inwardly in the lateral direction, for example, in the second direction D2, than one of at least one pad 130, disposed on the outermost side in the lateral direction, for example, the second direction D2. The margin portion 120 represents a case in which it does not include a conductor layer connected to the conductor layer 112 of the main portion 110 or does not include any conductor layer. In contrast, as illustrated in FIG. 8, the margin portion 120 may include a separate conductor layer 122, separated from the conductor layer 112 of the main portion 110. This separate conductor layer 122 may be used for various purposes as needed, for example, it can perform functions such as reinforcing the rigidity of the printed circuit board 100 and EMI shielding. In addition, as illustrated in FIG. 9, a portion of the conductor layers 112 may be disposed further outwardly in the lateral direction, than one of at least one pad 130 disposed on the outermost side in the lateral direction, for example, the second direction D2. In this case, the margin portion 120 may include a portion of the conductor layer 112 of the main portion 110.

### Method of Manufacturing a Printed Circuit Board

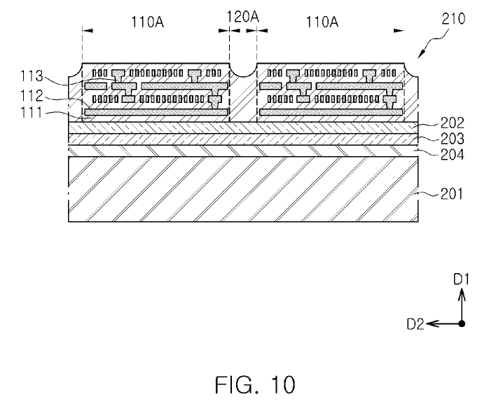

Hereinafter, examples of a method of manufacturing a printed circuit board will be described with reference to FIGS. 10 to 15. Each of processes in an example may be performed in a different order, unless the context clearly dictates a specific order.

First, as illustrated in FIG. 10, a substrate laminate 210 is formed on a carrier 201. The carrier 201 may be a hard substrate, such as glass, to minimize thermal deformation even at high temperatures, and may serve as a support when forming the substrate laminate 210. A seed layer 202 including a metal such as copper or titanium may be disposed on the carrier 201, a peeling layer 203 (or a release layer) for a subsequent de-bonding process may be disposed between the carrier 201 and the seed layer 202. The peeling layer 203, for example, may be formed of an inorganic insulating layer so that the peeling layer 203 may be stably peeled off even after a high-temperature reflow process. A bonding layer 204 containing a metal such as copper or titanium may be disposed between the carrier 201 and the peeling layer 203. The substrate laminate 210 may include a plurality of insulating layers 111 and a plurality of conductor layers 112, and conductive vias 113 connecting the plurality of conductor layers 112 may be provided. In the process of laminating a plurality of insulating layers 111 and a plurality of conductor layers 112, and forming conductive vias 113, a known method of manufacturing a printed circuit board may be utilized.

The substrate laminate 210 may be divided into a plurality of printed circuit board regions 110A and a margin region 120A therebetween. Here, the margin region 120A may correspond to a dicing region, and after dicing, it may be the margin portion 120 described above. As illustrated in the form in FIG. 10, the margin region 120A may be formed to have a relatively thin thickness because it does not include a conductor layer or has a smaller volume of the conductor layer than the printed circuit board region 110A, and accordingly, when the substrate laminate 210 is separated from the carrier 201, a portion of the substrate laminate 210 may not be separated. That is, an upper surface height of the margin region 120A may be lower than an upper surface height of the printed circuit board region 110A, and the greater this height difference, the more it may hinder structural stability during subsequent processes. Meanwhile, in FIG. 10, the substrate laminate 210 may be formed on one side of the carrier 201, but in order to improve process efficiency, the substrate laminate 210 may be formed on both sides (upper and lower sides based on the drawing) of the carrier 201.

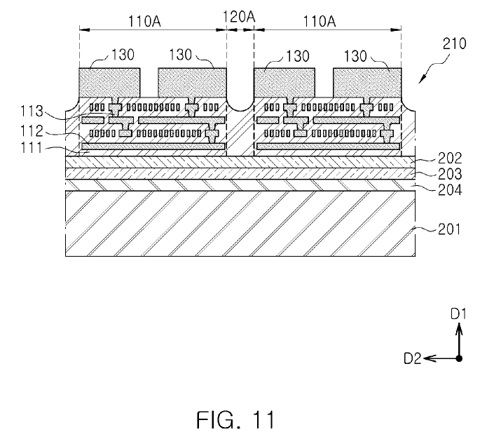

Next, as illustrated in FIG. 11, a plurality of pads 130 are formed on a plurality of printed circuit board regions 110A among the substrate laminates 210. The plurality of pads 130 may include a metal material such as copper (Cu), aluminum (Al), silver (Ag), tin (Sn), gold (Au), nickel (Ni), lead (Pb), titanium (Ti), or alloys thereof. The plurality of pads 130 may be formed by a plating process and, may include an electroless plating layer (or chemical copper) and an electrolytic plating layer (or electrolytic copper).

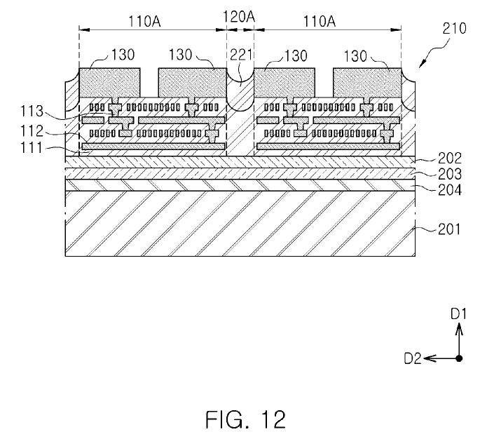

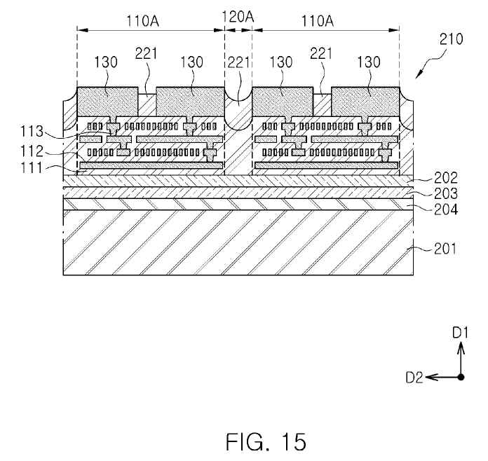

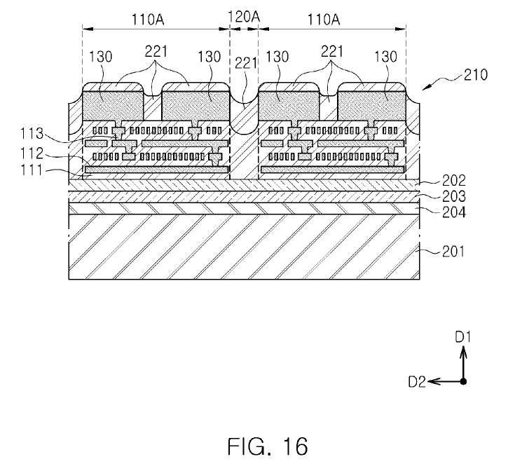

Next, as illustrated in FIG. 12, an insulator 221 is filled into a margin region 120A between adjacent regions of the plurality of printed circuit board regions 110A. In this case, the insulator 221 may be filled higher than a region, covered by a plurality of pads 130 on the upper surface of the substrate laminate 210. The insulator 221 may be formed to have a shape in which a height of the upper surface thereof decreases away from the pad 130, for example, to have a curved surface with a recessed center. However, the upper surface of the insulator 221 may also include a partially flat surface. The insulator 221 may be formed by selectively applying a liquid photosensitive resin to the margin region 120A, and may form an integral structure without distinguishing the boundary with the insulating layer 111 through a subsequent curing process. However, the insulator 221 may not be selectively applied only to the margin region 120A. For example, as in a modified example of FIG. 15, a portion of the insulator 221 may also be charged to the printed circuit board region 110A. In addition, as in a modified example of FIG. 16, the insulator 221 may be formed to cover a plurality of pads 130. In this case, an operation of removing at least a portion of the insulator 221 filled in the printed circuit board region 110A may be further performed. For example, the insulator 221 formed on the plurality of pads 130 may be removed through a subsequent etching process, and if necessary, a portion of the portion formed in a region between the plurality of pads 130 and the margin region 120A in the printed circuit board region 110A may also be removed.

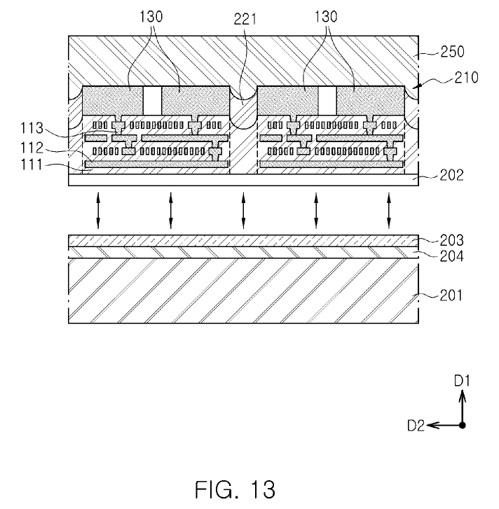

Next, as illustrated in FIG. 13, the substrate laminate 210 may be separated from the carrier 201, and to this end, a transfer substrate 250 may be attached on the substrate laminate 210. The transfer substrate 250 may include a material having adhesion so that the substrate laminate 210 may be separated from the carrier 201, and may include, for example, a PET material. In this case, as illustrated, at least a portion of the transfer substrate 250 may be in contact with the margin region 120A filled with the insulator 221, and accordingly, a de-bonding process may be effectively performed and a defect in which a portion of the substrate laminate 210 is not separated from the carrier 201 may be reduced. However, even when the transfer substrate 250 does not contact the margin region 120A, the printed circuit board regions 110A are stably bonded by the thickened margin region 120A, so that the de-bonding defect described above may be reduced. When the carrier 201 is separated, the seed layer 202 and the peeling layer 203 may be separated from each other, although separation may occur on different levels. In the case of the seed layer 202 bonded to the substrate laminate 210, at least a portion of the seed layer 202 may be removed in a subsequent process.

Next, as illustrated in FIG. 14, a region filled with the insulator 221, i.e., the margin region 120A, is diced (D) to separate the substrate laminate 210 into unit substrates. Accordingly, the unit substrates include the printed circuit board region 110A and a portion of the margin region 120A. As illustrated, the transfer substrate 250 may be separated from the substrate laminate 210 prior to a dicing process. For the dicing process, processes known in the printed circuit board industry, such as lasers or other mechanical separation methods, may be utilized. Meanwhile, while FIG. 14 shows the seed layer 202 removed before the dicing process, the seed layer 202 may also be removed after the dicing process.

### Printed Circuit Board including Bridge Substrate

Hereinafter, an example of using the printed circuit board described as a bridge substrate is described. In FIG. 17, the printed circuit board of FIG. 2 is indicated as a bridge substrate 100, and a mother board including the bridge substrate 100 is indicated as a printed circuit board 300. Referring to FIG. 17, the printed circuit board 300 includes a substrate portion 310 and a bridge substrate 100 embedded in the substrate portion 310. Here, as the bridge substrate 100, the printed circuit board described in the embodiment in FIG. 2 may be used, and in addition thereto, the printed circuit board of other embodiments described above may also be used. A detailed description of a specific structure of the bridge substrate 100 will be omitted. Since the bridge substrate 100 has the above-described structure, the bonding force between the margin portion 120 and the substrate portion 310 may be improved, and thereby, the structural stability of the printed circuit board 300 may be improved.

The substrate portion 310 may be, for example, a multilayer substrate, and may include a first insulating layer 311, a second insulating layer 321, a plurality of conductor patterns 312, and a plurality of first via layers 313. The bridge substrate 100 may be disposed in a recess of the substrate portion 310, and in this case, an adhesive may be used to bond the bridge substrate 100 to the substrate portion 310. The first insulating layer 311 may have a structure in which a plurality of insulating layers are laminated, and may include a thermosetting resin such as an epoxy resin, a thermoplastic resin such as a polyimide, or a material in which these resins are mixed with an inorganic filler such as silica, or a resin impregnated into a core material such as glass fiber (glass cloth, glass fabric) together with an inorganic filler, for example, an organic insulating material such as Copper Clad Laminate (CCL), Ajinomoto Build-up Film (ABF), or prepreg. The second insulating layer 321 may include CCL as a core layer, and in this case, a plurality of insulating layers may also be provided below the second insulating layer 321. The second insulating layer 321 may include other insulating materials, such as a glass plate, or the like, in addition to an organic insulating material, as needed.

The plurality of conductor patterns 312 may include a metal material, wherein the metal material may include copper (Cu), aluminum (Al), silver (Ag), tin (Sn), gold (Au), nickel (Ni), lead (Pb), titanium (Ti), or alloys thereof. The plurality of conductor patterns 312 may include an electroless plating layer (or chemical copper) and an electrolytic plating layer (or electrolytic copper), but an embodiment thereof is not limited thereto. A sputtering layer may be formed instead of a chemical copper, as an electroless plating layer, or both a sputtering layer and an electroless plating layer may be included. If necessary, copper foil may be further included. Each of the plurality of conductor patterns 312 may perform various functions depending on the design of a corresponding layer. For example, the plurality of conductor patterns 312 may include a ground pattern, a power pattern, a signal pattern, or the like. Each of these patterns may include a line pattern, a plain pattern, and/or a pad pattern. The conductor patterns of the bridge substrate 100 and the substrate portion 310 may have different pitches, and when considering the respective uses, the pitch of the bridge substrate 100 may be shorter. Specifically, an average distance between the plurality of conductor patterns included in the conductor layer 112 of the bridge substrate 100 may be less than an average distance between the plurality of conductor patterns 312 of the substrate portion 310.

The plurality of first via layers 313 may include a metal material, and the metal material may include copper (Cu), aluminum (Al), silver (Ag), tin (Sn), gold (Au), nickel (Ni), lead (Pb), titanium (Ti), and/or alloys thereof. The plurality of first via layers 313 may perform various functions depending on a design of the corresponding layer. For example, the via layer 313 may include a ground via, a power via, a signal via, and the like. The via layer 313 may include an electroless plating layer (or chemical copper) and an electrolytic plating layer (or electrical copper), respectively, but an embodiment thereof is not limited thereto. A sputtering layer may be formed instead of a chemical copper, as an electroless plating layer, or both a sputtering layer and an electroless plating layer may be included. The plurality of first via layers 313 may include microvias. Here, the microvias may be a filled via filling a via hole or a conformal via disposed along a wall surface of the via hole. The microvias may be disposed in laminated type and/or staggered type. The microvias may have a tapered shape. A second insulating layer 321 may be provided with a through-via 322 penetrating therethrough. The through-via 322 may include a metal layer formed on a wall surface of the through-hole and a plug filling the metal layer. The through-via 322 may have a cylindrical shape, but an embodiment thereof is not limited thereto, and the through-via 322 may also have an hourglass shape.

As illustrated in the diagram, a bridge substrate 100 may be disposed in a recess (R) of the substrate portion 310. In this case, an insulating material 331 may be provided to cover the bridge substrate 100 by filling the recess (R). As an example, the insulating material 331 may fill a space between the recess (R) and the bridge substrate 100, and may extend onto each of the recess (R) and the bridge substrate 100 to cover one surface of each of the recess (R) and the bridge substrate 100. An insulating material may be used as a forming material of the insulating material 331, and for example, Ajinomoto build-up film (ABF) may be used, but an embodiment thereof is not limited thereto. When the bridge substrate 100 is manufactured separately and disposed on the substrate portion 310, the insulating material 331 may form an interface with the insulator 121 of the margin portion 120 of the bridge substrate 100. In addition, the insulating material 331 and the insulator 121 of the margin portion 120 may contain different materials.

Meanwhile, the printed circuit board 300 may further include a plurality of second via layers 333 penetrating through the insulating material 331 and connected to the pad 130 of the bridge substrate 100. The second via layers 333 may be applied in substantially the same form as the first via layer 313 described above. A plurality of second conductor patterns 332 connected to the second via layer 333 may be disposed on an upper portion of the insulating material 331, and the plurality of second conductor patterns 332 may be in the form of pads. The printed circuit board 300 may further include a protective layer 341 disposed on the insulating material 331 and having an opening exposing at least a portion of the conductor pattern 152. The protective layer 341 may include ABF or solder resist, but an embodiment thereof is not limited thereto. In addition, the printed circuit board 300 may further include a connection conductor 342 disposed on the protective layer 341 and connected to the second conductor pattern 332. A conductive material may be used as a forming material of the connection conductor 342, and for example, a conductive post and/or solder ball may be used.

In the present disclosure, the meaning on a cross-section may refer to a cross-sectional shape when an object is cut vertically, or a cross-sectional shape when the object is viewed from the side. Furthermore, the meaning on a plane may refer to a planar shape when the object is horizontally cut, or a planar shape when the object is viewed from the top or the bottom.

In the present disclosure, for convenience, an upper side, an upper portion, and an upper surface are used to refer to a downward direction with respect to a cross-section of a drawing, and a lower side, a lower portion, and a lower surface are used to refer to an opposite direction thereof. However, this is a definition of direction for the convenience of explanation, and the scope of the claim is not specifically limited by the description of this direction, and the concept of upper/lower may be changed at any time.

In the present disclosure, the thickness, width, length, depth, or the like may be measured using a scanning microscope or optical microscope, respectively, based on a cross-section of a polished or cut printed circuit board. The cut cross-section may be a vertical cross-section or a horizontal cross-section, and each value thereof may be measured based on the required cut section. When a numerical value is not constant, the numerical value may be determined as an average value of the values measured at five random points. A width of an upper end portion and/or a lower end portion of a via or a recess portion may be measured on a cross-section taken along a central axis of the substrate in a thickness direction. In the present disclosure, a pitch may be measured by photographing a cut cross-section of a printed circuit board using scanning microscope or an optical microscope, and an average pitch may be an average value of a pitch between wirings measured at any five points.

In the present disclosure, the meaning of being connected is a concept including not only directly connected but also indirectly connected through an adhesive layer or the like. Furthermore, the meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression of example embodiment used in the present disclosure does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

As set forth above, in the case of a printed circuit board according to an example of the present disclosure, structural stability may be improved. In particular, when such a printed circuit board is used as a bridge substrate, the mountability within a mother board may be significantly improved, thereby improving the performance and reliability of the printed circuit board. In addition, a printed circuit board may be efficiently implemented through a method for manufacturing a printed circuit board according to an example of the present disclosure.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a main portion including a plurality of insulating layers and a plurality of conductor layers, laminated in a first direction;
a margin portion disposed on an outside of the main portion in a second direction, and including an insulator connected to the insulating layers of the main portion; and
at least one pad disposed on the main portion,
wherein, when a portion of an upper surface of the main portion, covered by the at least one pad is referred to as a cover surface, and a portion of the upper surface, not covered by the at least one pad is referred to as an open surface,
at least a portion of an upper surface of the margin portion is located above the cover surface based on the first direction.

2. The printed circuit board of claim 1, wherein the insulating layers of the main portion and the insulator of the margin portion forms an integral structure.

3. The printed circuit board of claim 1, wherein in the margin portion, a region located above the cover surface and a region located below the cover surface form an integral structure.

4. The printed circuit board of claim 1, wherein the insulating layers of the main portion and the insulator of the margin portion are formed of the same material.

5. The printed circuit board of claim 1, wherein the margin portion does not include a conductor layer connected to the conductor layers of the main portion.

6. The printed circuit board of claim 1, wherein the margin portion does not include a conductor layer.

7. The printed circuit board of claim 1, wherein a portion of the margin portion is in contact with a side surface of the at least one pad.

8. The printed circuit board of claim 1, wherein an outer surface of the margin portion is a cut surface.

9. The printed circuit board of claim 1, wherein when directions, perpendicular to the first direction and perpendicular to each other, is referred to as the second direction and a third direction,
the margin portion is disposed on the outside of the main portion in the second direction and the third direction.

10. The printed circuit board of claim 1, wherein the upper surface of the margin portion has a height decreasing toward an outer edge in the second direction.

11. The printed circuit board of claim 1, wherein the upper surface of the margin portion includes a curved surface having a recessed form.

12. The printed circuit board of claim 1, wherein all regions of the upper surface of the margin portion are located above the cover surface of the main portion.

13. The printed circuit board of claim 1, wherein at least a portion of the upper surface of the margin portion is located below an upper surface of the at least one pad.

14. The printed circuit board of claim 13, wherein all regions of the upper surface of the margin portion are located below the upper surface of the at least one pad.

15. The printed circuit board of claim 1, wherein based on the first direction, the cover surface and the open surface are located on substantially the same level.

16. The printed circuit board of claim 14, wherein the open surface is substantially flat.

17. The printed circuit board of claim 1, wherein based on the first direction, the open surface is located above the cover surface.

18. The printed circuit board of claim 17, wherein the open surface comprises a curved surface.

19. The printed circuit board of claim 17, wherein based on the first direction, at least a portion of the upper surface of the margin portion is located below the open surface.

20. The printed circuit board of claim 19, wherein the open surface is substantially flat.

21. The printed circuit board of claim 20, wherein an uppermost portion of the upper surface of the margin portion is located on substantially the same level as the open surface.

22. The printed circuit board of claim 17, wherein based on the first direction, at least a portion of the upper surface of the margin portion is located above the open surface.

23. The printed circuit board of claim 1, wherein the at least one pad is provided in plural, and a distance between adjacent pads among a plurality of pads is less than a width of the margin portion.

24. The printed circuit board of claim 23, wherein the open surface is substantially flat, and
the upper surface of the margin portion includes a curved surface.

25. The printed circuit board of claim 1, wherein the upper surface of the margin portion is substantially flat.

26. The printed circuit board of claim 1, wherein the conductor layers is disposed further inwardly in the second direction than one of the at least one pad, disposed on an outermost side in the second direction.

27. The printed circuit board of claim 1, wherein the margin portion comprises a separate conductor layer, separated from the conductor layers of the main portion.

28. The printed circuit board of claim 1, wherein a portion of the conductor layers are disposed further outwardly in the second direction than one of the at least one pad, disposed on an outermost side in the second direction.

29. The printed circuit board of claim 28, wherein the margin portion comprises a portion of the conductor layers of the main portion.

30. A printed circuit board, comprising:
a substrate portion; and
a bridge substrate embedded in the substrate portion,
wherein the bridge substrate includes:
a main portion including a plurality of insulating layers and a plurality of conductor layers laminated in a first direction;
a margin portion disposed on an outside of the main portion in a second direction, and including an insulator connected to the insulating layers of the main portion; and
at least one pad disposed on the main portion,
wherein at least a portion of an upper surface of the margin portion is located above a lower surface of the at least one pad based on the first direction.

31. The printed circuit board of claim 30, wherein the bridge substrate is disposed in a recess of the substrate portion.

32. The printed circuit board of claim 31, further comprising:
an insulating material covering the bridge substrate by filling the recess.

33. The printed circuit board of claim 32, wherein the insulating material forms an interface with the insulator of the margin portion.

34. The printed circuit board of claim 33, wherein the insulating material and the insulator of the margin portion contain different materials.

35. The printed circuit board of claim 32, further comprising:
a plurality of via layers penetrating through the insulating material and connected to the at least one pad of the bridge substrate.

36. The printed circuit board of claim 30, wherein the conductor layers of the bridge substrate comprise a plurality of conductor patterns and the substrate portion comprises a plurality of conductor patterns, and
an average distance between the plurality of conductor patterns of the bridge substrate is less than an average distance between the plurality of conductor patterns of the substrate portion.

37. A method of manufacturing a printed circuit board, comprising:
forming a substrate laminate by laminating a plurality of insulating layers and a plurality of conductor layers;
forming a plurality of pads on a plurality of printed circuit board regions of the substrate laminate;
filling an insulator into a margin region between adjacent regions of the plurality of printed circuit board regions; and
separating the substrate laminate into unit substrates by dicing the margin region filled with the insulator.

38. The method of claim 37, wherein the forming of the substrate laminate includes preparing a carrier, and repeatedly forming the plurality of insulating layers and the plurality of conductor layers on the carrier.

39. The method of claim 38, further comprising:
attaching a transfer substrate to the substrate laminate; and
separating the carrier from the substrate laminate.

40. The method of claim 37, wherein before the filling of the insulator, an upper surface of the margin region is lower in height than an upper surface of the printed circuit board regions.

41. The method of claim 40, wherein in the filling of the insulator, the insulator is filled higher than a region of an upper surface of the substrate laminate, covered by the plurality of pads.

42. The method of claim 37, wherein in the filling of the insulator, a portion of the insulator is filled on the printed circuit board regions.

43. The method of claim 42, wherein in the filling of the insulator, a portion of the insulator covers the plurality of pads.

44. The method of a printed circuit board of claim 43, further comprising:
removing at least a portion of the insulator, filled into the printed circuit board regions.
